(19) United States
(12) Patent Application Publication
(10) Pub. No.: US 2026/0076006 A1
(43) Pub. Date: Mar. 12, 2026

(54) DISPLAY DEVICE

(71) Applicant: LG Display Co., Ltd., Seoul (KR)

(72) Inventors: Sungmoo KIM, Goyang-si (KR); Heumeil BAEK, Seoul (KR)

(73) Assignee: LG Display Co., Ltd., Seoul (KR)

(21) Appl. No.: 19/285,569

(22) Filed: Jul. 30, 2025

(30) Foreign Application Priority Data
Sep. 9, 2024 (KR) 10-2024-0122610

(51) Int. Cl. H10H 29/37; H01L 25/075

(52) U.S. Cl. CPC H10H 29/37; H10W 90/00

(57) ABSTRACT

A display device can include a substrate having a plurality of sub pixels, a black bank surrounding each of the plurality of sub pixels, and a plurality of light emitting diodes in the plurality of sub pixels. The plurality of light emitting diodes includes a first light emitting diode and a second light emitting diode disposed in each of the plurality of sub pixels and configured to emit the same color light. A shortest distance between the first light emitting diode and the black bank is longer than a shortest distance between the second light emitting diode and the black bank. Therefore, a left viewing angle and a right viewing angle are set to be different to restrict image output in a specific direction.

### CROSS-REFERENCE TO RELATED APPLICATIONS

This application claims priority to Korean Patent Application No. 10-2024-0122610 filed on Sep. 9, 2024, in the Korean Intellectual Property Office, the entire disclosure of which is hereby expressly incorporated by reference into the present application

### BACKGROUND

### Field

The present disclosure relates to an apparatus and particularly to, for example, without limitation, a display device, and more particularly, to a display device using a light emitting diode (LED).

### Discussion of the Related Art

As the technology in modern society develops, display devices are used in various ways to provide information to users. The display devices include not only electronic signs which simply transmit visual information in one direction, but also various electronic devices which require higher level of technology to check the user's input and provide information in response to the checked input.

For example, a display device is included in a vehicle to provide various information to a driver and a co-driver of the vehicle.

The description provided in the discussion of the related art section should not be assumed to be prior art merely because it is mentioned in or associated with that section. The discussion of the related art section can include information that describes one or more aspects of the subject technology, and the description in this section does not limit the disclosure.

### SUMMARY OF THE DISCLOSURE

The inventors of the present disclosure have recognized that the display device of a vehicle needs to appropriately display contents without interrupting the operation of the vehicle. For example, the display device needs to limit the display of the contents which can reduce the concentration on the driving while the vehicle is in operation.

An object to be achieved by the present disclosure is to provide a display device in which a viewing angle characteristic varies depending on a position of a light emitting diode.

Another object to be achieved by the present disclosure is to provide a display device in which a viewing angle characteristic varies depending on a height of a black bank.

Still another object to be achieved by the present disclosure is to provide a display device which adjusts a viewing angle by driving different light emitting diodes depending on a driving state and a stop state.

Objects of the present disclosure are not limited to the above-mentioned objects, and other objects, which are not mentioned above, can be clearly understood by those skilled in the art from the following descriptions.

According to an aspect of the present disclosure, a display device includes a substrate including a plurality of sub pixels, a black bank surrounding each of the plurality of sub pixels, and a plurality of light emitting diodes in the plurality of sub pixels. The plurality of light emitting diodes includes a first light emitting diode and a second light emitting diode disposed in each of the plurality of sub pixels and emitting the same color light. A shortest distance between the first light emitting diode and the black bank is longer than a shortest distance between the second light emitting diode and the black bank.

According to another aspect of the present disclosure, a display device includes a substrate including a plurality of sub pixels, a plurality of light emitting diodes in the plurality of sub pixels, and a black bank surrounding each of the plurality of sub pixels. The plurality of light emitting diodes includes a first light emitting diode in each of the plurality of sub pixels and a second light emitting diode emitting the same color light as the first light emitting diode. The black bank has different heights in one side and the other side of the plurality of sub pixels.

Other detailed matters of the example embodiments of the present disclosure are included in the detailed description and the drawings.

According to aspects of the present disclosure, a left viewing angle and a right viewing angle are set to be different to restrict image output in a specific direction.

According to aspects of the present disclosure, the viewing angle is adjusted by the black bank to optimize the process.

According to aspects of the present disclosure, a distance between the light emitting diode and the black bank is adjusted to adjust a viewing angle.

The effects according to the present disclosure are not limited to the contents exemplified above, and more various effects are included in the present disclosure.

It is to be understood that both the foregoing general description and the following detailed description are examples and explanatory and are intended to provide further explanation of the inventive concepts as claimed.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is an example of a display device according to an example embodiment of the present disclosure;

FIG. 2 is a schematic diagram of a display device according to an example embodiment of the present disclosure;

FIG. 3 is an enlarged plan view of a display area of a display device according to an example embodiment of the present disclosure;

FIG. 4 is a cross-sectional view of a sub pixel of a display device according to an example embodiment of the present disclosure;

FIG. 5A is a schematic view illustrating a viewing angle of a first light emitting diode of a display device according to an example embodiment of the present disclosure;

FIG. 5B is a schematic view illustrating a viewing angle of a second light emitting diode of a display device according to an example embodiment of the present disclosure;

FIG. 6 is an enlarged plan view of a display area of a display device according to another example embodiment of the present disclosure;

FIG. 7 is a cross-sectional view of a sub pixel of a display device according to another example embodiment of the present disclosure; and

FIG. 8 is a schematic view of a viewing angle of a sub pixel of a display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous can be included unless a more limiting term, such as “just,” “immediate(ly),” or “direct(ly)” is used.

Further, when an element or layer is “connected,” “coupled,” or “adhered” to another element or layer denotes that the element or layer can not only be directly connected or adhered to the other element or layer, but also be indirectly connected or adhered to the other element or layer with one or more intervening elements or layers “disposed,” or “interposed” between the elements or layers, unless otherwise specified. It should be understood to mean that elements can be so disposed to directly contact each other, or can be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may” and vice versa.

Rather, these embodiments can be provided so that this disclosure can be sufficiently thorough and complete to assist those skilled in the art to fully understand the scope of the present disclosure.

Hereinafter, various embodiments of the present disclosure will be described in detail with reference to accompanying drawings. All the components of each display device/apparatus according to all embodiments of the present disclosure are operatively coupled and configured.

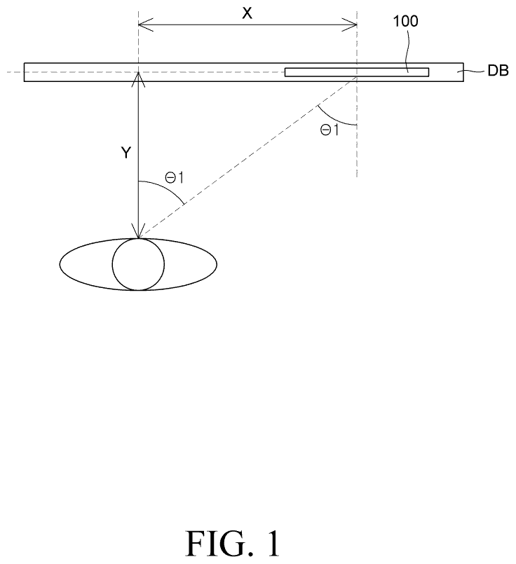

FIG. 1 is an example of a display device according to an example embodiment of the present disclosure.

Referring to FIG. 1, a display device 100 can be disposed in at least a part of a dash board DB of a vehicle. The vehicle dash board DB includes a configuration which is disposed on a front surface of a front seat of the vehicle. For example, on the dash board DB of the vehicle, an input configuration for manipulating various functions (for example, an air-conditioner, an audio system, or a navigation system) in the vehicle can be disposed.

The display device 100 can be disposed in the front surface direction of a co-driver seat of the dash board DB. For example, the display device 100 can be a co-driver display CDD. Accordingly, the display device 100 according to the example embodiment of the present disclosure is disposed on the dash board DB of the vehicle to provide convenience of a co-driver in the co-driver seat. For example, the display device 100 can provide information which is irrelevant to the vehicle operation, for example, information about entertainment, such as dramas, movies, or music.

The display device 100 can be disposed in a side surface direction of the driver seat. For example, an angle of a normal line of the display device 100 and a driver of the driver seat at the center of the display device 100 can be a first angle θ1. For example, when a vertical distance between the display device 100 (or the dash board DB) and the driver is Y and a horizontal distance between the driver and the center of the display device 100 is X, tan θ1=X/Y. For example, when X is 100 cm and Y is 80 cm, the first angle θ1 can be approximately 52 degrees, but is not limited thereto.

The display device 100 can selectively provide images of the display device 100 to the driver according to a mode. For example, in a first mode in which the vehicle is stopped, the display device 100 can emit light having a viewing angle larger than the first angle θ1 toward the driver seat. When the first angle θ1 is approximately 52 degrees, in the first mode, the display device 100 can emit light having a viewing angle of approximately 60 degrees toward the driver seat. Accordingly, in the first mode, the driver and the co-driver can watch the image of the display device 100 together.

Further, in a second mode in which the vehicle is being driven, the display device 100 can emit light having a viewing angle smaller than the first angle θ1 toward the driver seat. For example, when the first angle θ1 is approximately 52 degrees, in the second mode, the display device 100 can emit light having a viewing angle of approximately 50 degrees toward the driver seat. Accordingly, in the second mode, the co-driver can watch the image of the display device 100, but the driver can be restricted from watching the image of the display device 100.

Therefore, when the display device 100 is driven in the first mode in a state in which the vehicle is stopped, the driver and the co-driver can watch the image of the display device 100 together. Further, when the display device 100 is driven in the second mode in a state in which the vehicle is being driven, only the co-driver watches the image of the display device 100 to ensure the safety of the vehicle operation.

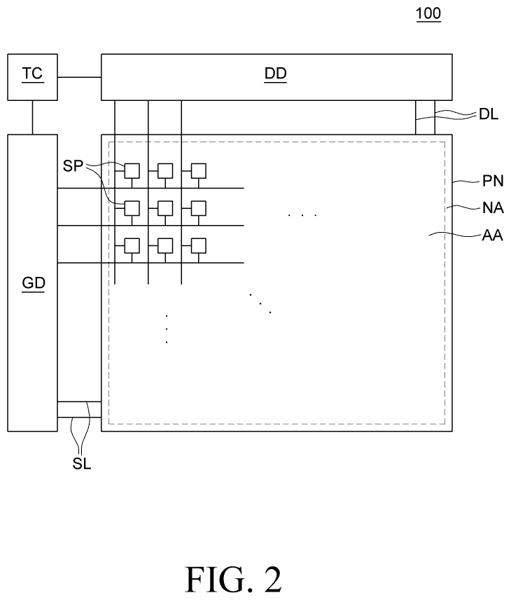

FIG. 2 is a schematic diagram of a display device according to an example embodiment of the present disclosure. In FIG. 2, for the convenience of description, among various components of the display device 100, a display panel PN, a gate driver GD, a data driver DD, and a timing controller TC are illustrated.

Referring to FIG. 2, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 2, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD converts the image data into a data voltage using a reference gamma voltage and can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP can be formed at intersections of the scan lines SL and the data lines DL.

In the display panel PN, a display area (or an active area) AA and a non-display area (or a non-active area) NA can be defined.

The display area AA is an area in which images are displayed in the display device 100. In the display area AA, a plurality of sub pixels SP which configures a plurality of pixels PX and a pixel circuit for driving the plurality of sub pixels SP can be disposed. The plurality of sub pixels SP is a minimum unit which configures the display area AA and n sub pixels SP form one pixel PX. In each of the plurality of sub pixels SP, a thin film transistor for driving the plurality of light emitting diodes can be disposed. The plurality of light emitting diodes can be defined in different manners depending on the type of the display panel PN. For example, when the display panel PN is an inorganic light emitting display panel PN, the light emitting diode can be a light emitting diode (LED) or a micro light emitting diode (LED).

In the display area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the display area AA to be connected to the plurality of sub pixels SP and the plurality of data lines DL extends to a direction different from the one direction in the display area AA to be connected to the plurality of sub pixels SP. In addition, in the display area AA, a low potential power line and a high potential power line can be further disposed, but are not limited thereto.

The non-display area NA is an area where images are not displayed so that the non-display area NA can be defined as an area extending from the display area AA. In the non-display area NA, a link line which transmits a signal to the sub pixel SP of the display area AA, a pad electrode, or a driving integrated circuit (IC), such as a gate driver IC or a data driver IC, can be disposed.

In the meantime, the non-display area NA can be located on a rear surface of the display panel PN, for example, a surface on which the sub pixels SP are not disposed or can be omitted, and is not limited as illustrated in the drawing.

In the meantime, a driver, such as a gate driver GD, a data driver DD, and a timing controller TC, can be connected to the display panel PN in various ways. For example, the gate driver GD can be mounted in the non-display area NA in a gate in panel (GIP) manner or mounted between the plurality of sub pixels SP in the display area AA in a gate in active area (GIA) manner.

For example, the data driver DD and the timing controller TC are formed in separate flexible film and printed circuit board. The display panel PN can be electrically connected to the data driver DD and the timing controller TC by bonding the flexible film and the printed circuit board to the pad electrode formed in the non-display area NA of the display panel PN.

As another example, when the gate driver GD is mounted in the display area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-display area NA on the front surface of the display panel PN can be minimized or reduced. Therefore, when the gate driver GD, the data driver DD, and the timing controller TC are connected to the display panel PN as described above, a zero bezel with substantially no bezel can be implemented.

Hereinafter, a display panel PN of a display device 100 according to an example embodiment of the present disclosure will be described in more detail.

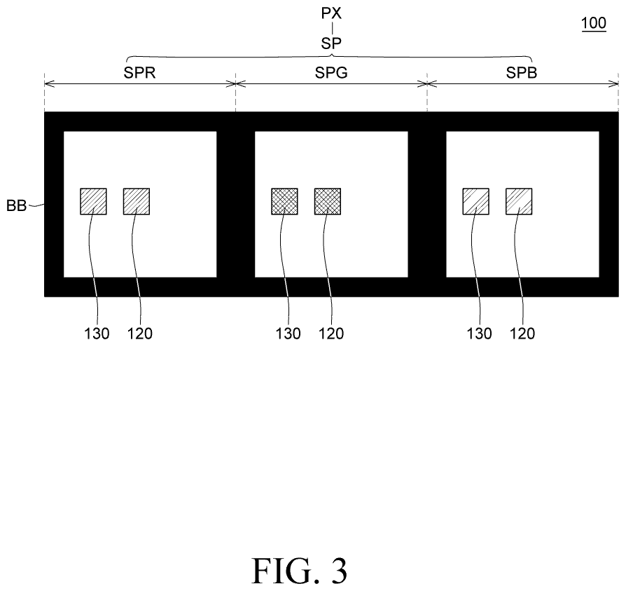

FIG. 3 is an enlarged plan view of a display area of a display device according to an example embodiment of the present disclosure.

Referring to FIG. 3, the display device 100 according to the example embodiment of the present disclosure can include a plurality of pixels PX each including a plurality of sub pixels SP. Each of the plurality of sub pixels SP includes a plurality of light emitting diodes and a plurality of pixel circuits to independently emit light. One pixel PX can include one or more red sub pixels SPR, one or more green sub pixels SPG, and one or more blue sub pixels SPB. In the meantime, the plurality of pixels PX can further include a sub pixel SP which emits another color light, other than the red sub pixel SPR, the green sub pixel SPG, and the blue sub pixel SPB, but is not limited thereto.

The red sub pixel SPR, the green sub pixel SPG, and the blue sub pixel SPB can be disposed along one direction. For example, the red sub pixel SPR, the green sub pixel SPG, and the blue sub pixel SPB can be disposed along a row direction.

Each of the plurality of sub pixels SP includes a first light emitting diode 120 and a second light emitting diode 130. For example, each of the red sub pixel SPR, the green sub pixel SPG, and the blue sub pixel SPB can include the first light emitting diode 120 and the second light emitting diode 130.

The first light emitting diode 120 and the second light emitting diode 130 which are disposed in the same sub pixel SP can be light emitting diodes which emit light with the same color. For example, the first light emitting diode 120 and the second light emitting diode 130 disposed in the red sub pixel SPR can be light emitting diodes which emit same red light. The first light emitting diode 120 and the second light emitting diode 130 disposed in the green sub pixel SPG can be light emitting diodes which emit same green light and the first light emitting diode 120 and the second light emitting diode 130 disposed in the blue sub pixel SPB can be light emitting diodes which emit same blue light.

The first light emitting diode 120 and the second light emitting diode 130 can be disposed in the same row and different columns. In the column direction, an interval between the first light emitting diode 120 and the black bank BB can be the same as an interval between the second light emitting diode 130 and the black bank BB. In contrast, in the row direction, an interval between the first light emitting diode 120 and the black bank BB is different from an interval between the second light emitting diode 130 and the black bank BB.

The first light emitting diode 120 can be disposed in a center portion of each sub pixel SP. For example, in the row direction, the first light emitting diode 120 can have the same interval with the left and right black banks BB, but is not limited thereto. Further, the interval between the first light emitting diode 120 and the left black bank BB can be different from the interval between the first light emitting diode 120 and the right black bank BB.

The second light emitting diode 130 can be disposed to be biased to one side in each sub pixel SP. For example, the second light emitting diode 130 can be disposed on the left side of the first light emitting diode 120. Therefore, the second light emitting diode 130 can be disposed between the black bank BB and the first light emitting diode 120. Therefore, in the row direction, the shortest distance between the first light emitting diode 120 and the black bank BB is longer than the shortest distance between the second light emitting diode 130 and the black bank BB.

In one sub pixel SP, only one of the first light emitting diode 120 and the second light emitting diode 130 can be selectively driven. For example, the first light emitting diode 120 and the second light emitting diode 130 can be connected to different transistors. Therefore, the transistors connected to the first light emitting diode 120 and the second light emitting diode 130 are independently driven according to the mode so that only one of the first light emitting diode 120 and the second light emitting diode 130 can be selectively driven.

At this time, the mode can be specified by the user's input or determined when a predetermined condition is satisfied. For example, when a predetermined first condition is satisfied, the first light emitting diode 120 can emit light as a first mode signal is supplied. When a predetermined second condition is satisfied, the second light emitting diode 130 can emit light as the second mode signal is supplied. The first condition can include a condition which is specified in advance to be driven in the first mode. The second condition can include a condition which is specified in advance to be driven in the second mode. For example, the first condition can be a state in which the vehicle is stopped and the second condition can be a state in which the vehicle is being driven. Accordingly, the first light emitting diode 120 can be driven when the vehicle is in a stopped state and the second light emitting diode 130 can be driven when the vehicle is in a driving state.

The first light emitting diode 120 can be configured to allow light emitted from the first light emitting diode 120 to have a wide viewing angle in a driver seat direction and a co-driver seat direction. Accordingly, light emitted from the first light emitting diode 120 can be visible to both the driver and the co-driver.

The second light emitting diode 130 can be configured to allow light emitted from the second light emitting diode 130 to have a narrow viewing angle in a drive seat direction and a wide viewing angle in a co-driver seat direction. Accordingly, light emitted from the second light emitting diode 130 can be not visible to the driver, but be visible to the co-driver.

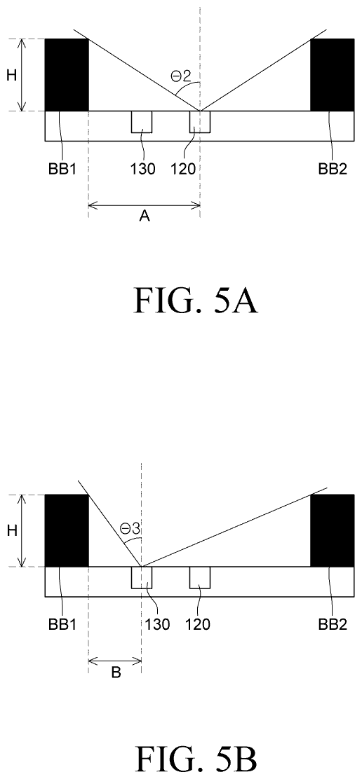

The viewing angles of the first light emitting diode 120 and the second light emitting diode 130 will be described in detail below with reference to FIGS. 5A and 5B.

The black bank BB is disposed between the plurality of sub pixels SP. The black bank BB is disposed so as to surround each of the plurality of sub pixels to shield the light emitted from each sub pixel PX so as not to be mixed or interfered and suppress the external light reflection. The black bank BB can limit the viewing angle of the first light emitting diode 120 and the second light emitting diode 130.

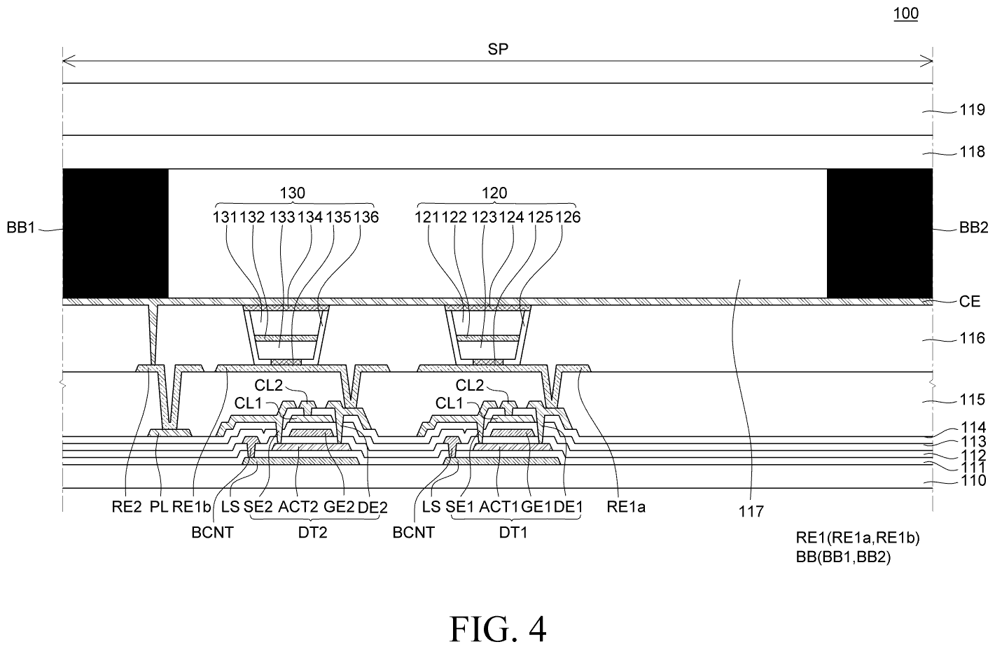

Hereinafter, the plurality of sub pixels SP will be described in more detail with reference to FIG. 4.

FIG. 4 is a cross-sectional view of a sub pixel of a display device according to an example embodiment of the present disclosure.

Referring to FIG. 4, a first substrate 110 is a component for supporting various components included in the display device 100 and can be formed of an insulating material. For example, the first substrate 110 can be formed of glass or resin. Further, the first substrate 110 can be configured to include polymer or plastics or can be formed of a material having flexibility.

A light shielding layer LS is disposed in each of the plurality of sub pixels SP on the first substrate 110. The light shielding layer LS blocks light incident to a first active layer ACT1 of a first driving transistor DT1 and a second active layer ACT2 of a second driving transistor DT2 from the bottom of the first substrate 110. In the light shielding layer LS, light which is incident to the first active layer ACT1 of the first driving transistor DT1 and the second active layer ACT2 of the second driving transistor DT2 is blocked to minimize or reduce the leakage current.

A buffer layer 111 is disposed on the first substrate 110 and the light shielding layer LS. The buffer layer 111 can reduce permeation of moisture or impurities through the first substrate 110. The buffer layer 111 can be configured by a single layer or a double layer of silicon oxide (SiOx) or silicon nitride (SiNx), but is not limited thereto. However, the buffer layer 111 can be omitted depending on a type of the first substrate 110 or a type of transistor, but is not limited thereto.

The first driving transistor DT1 and the second driving transistor DT2 are disposed on the buffer layer 111.

The first driving transistor DT1 includes a first active layer ACT1, a first gate electrode GE1, a first source electrode SE1, and a first drain electrode DE1.

The first active layer ACT1 is disposed on the buffer layer 111. The first active layer ACT1 can be formed of a semiconductor material such as an oxide semiconductor, amorphous silicon, or polysilicon, but is not limited thereto.

The gate insulating layer 112 is disposed on the first active layer ACT1. The gate insulating layer 112 is an insulating layer which insulates the first active layer ACT1 from the first gate electrode GE1 and can be configured by a single layer or a double layer of silicon oxide (SiOx) or silicon nitride (SiNx), but is not limited thereto.

The first gate electrode GE1 is disposed on the gate insulating layer 112. The first gate electrode GE1 can be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the first gate electrode GE1. Contact holes through which the first source electrode SE1 and the first drain electrode DE1 are connected to the first active layer ACT1 can be formed in the first interlayer insulating layer 113 and the second interlayer insulating layer 114, respectively. The first interlayer insulating layer 113 and the second interlayer insulating layer 114 are insulating layers for protecting a component below the first interlayer insulating layer 113 and the second interlayer insulating layer 114 and can be configured by a single layer or a double layer of silicon oxide (SiOx) or silicon nitride (SiNx), but are not limited thereto.

A first source electrode SE1 and a first drain electrode DE1 which are electrically connected to the first active layer ACT1 are disposed on the second interlayer insulating layer 114. The first source electrode SE1 and the first drain electrode DE1 can be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113 and the second interlayer insulating layer 114, for example, a plurality of insulating layers is disposed between the first gate electrode GE1 and the first source electrode SE1 and the first drain electrode DE1. However, only one insulating layer can be disposed between the first gate electrode GE1 and the first source electrode SE1 and the first drain electrode DE1, but is not limited thereto.

The second driving transistor DT2 includes a second active layer ACT2, a second gate electrode GE2, a second source electrode SE2, and a second drain electrode DE2.

The second active layer ACT2 is disposed on the buffer layer 111. The second active layer ACT2 can be formed on the same layer as the first active layer ACT1 with the same material.

The gate insulating layer 112 is disposed on the second active layer ACT2 and the second gate electrode GE2 is disposed on the gate insulating layer 112. The second gate electrode GE2 can be formed on the same layer as the first gate electrode GE1 with the same material.

The first interlayer insulating layer 113 and the second interlayer insulating layer 114 are disposed on the second gate electrode GE2 and the second source electrode SE2 and the second drain electrode DE2 which are electrically connected to the second active layer ACT2 are disposed on the first interlayer insulating layer 113 and the second interlayer insulating layer 114. The second source electrode SE2 and the second drain electrode DE2 can be formed on the same layer as the first source electrode SE1 and the first drain electrode DE1 with the same material.

Further, when a plurality of insulating layers, such as the first interlayer insulating layer 113 and the second interlayer insulating layer 114, is disposed between the first gate electrode GE1 and the first source electrode SE1 and the first drain electrode DE1 and between the second gate electrode GE2 and the second source electrode SE2 and the second drain electrode DE2, an electrode can be further formed between the first interlayer insulating layer 113 and the second interlayer insulating layer 114. The additionally formed electrode can form a capacitor with the other configuration disposed below first interlayer insulating layer 113 or above the second interlayer insulating layer 114.

For example, a first conductive layer CL1 is disposed between the first interlayer insulating layer 113 and the second interlayer insulating layer 114 and a second conductive layer CL2 which is electrically connected to the first conductive layer CL1 can be disposed on the second interlayer insulating layer 114. The first conductive layer CL1 and the second conductive layer CL2 are disposed so as to overlap the first gate electrode GE1 of the first driving transistor DT1 to form a capacitor with the first gate electrode GE1 of the first driving transistor DTL. Further, the first conductive layer CL1 and the second conductive layer CL2 are disposed so as to overlap the second gate electrode GE2 of the second driving transistor DT2 to form a capacitor with the second gate electrode GE2 of the second driving transistor DT2. Accordingly, various conductive layers, such as the first conductive layer CL1 and the second conductive layer CL2, are disposed on the first substrate 110 to form a capacitor.

Next, an auxiliary electrode BCNT is disposed on the gate insulating layer 112. The auxiliary electrode BCNT is an electrode for applying a voltage to the light shielding layer LS below the buffer layer 111. For example, the light shielding layer LS is electrically connected to another configuration disposed on the first substrate 110 by means of the auxiliary electrode BCNT to be applied with a voltage. The light shielding layer LS which is applied with a voltage by means of the auxiliary electrode BCNT does not operate as a floating gate and can minimize or reduce a fluctuation of a threshold voltage of the first driving transistor DT1 which is generated by the floated light shielding layer LS and can minimize or reduce a fluctuation of a threshold voltage of the second driving transistor DT2.

The power line PL is disposed on the second interlayer insulting layer 114. The power line PL is electrically connected to the first light emitting diode 120 together with the first driving transistor DT1 to allow the first light emitting diode 120 to emit light. Further, the power line PL is electrically connected to the second light emitting diode 130 together with the second driving transistor DT2 to allow the second light emitting diode 130 to emit light. The power line PL can be configured by a conductive material such as copper (Cu), aluminum (Al), molybdenum (Mo), nickel (Ni), titanium (Ti), chrome (Cr), or an alloy thereof, but is not limited thereto.

The organic insulating layer 115 is disposed on the first driving transistor DT1, and the second driving transistor DT2, and the power line PL. The organic insulating layer 115 can planarize an upper portion of the first substrate 110 on which the first driving transistor DT1 and the second driving transistor DT2 are disposed. The organic insulating layer 115 can be configured by a single layer or a double layer, and for example, can be formed of photoresist or an acrylic-based organic material, but is not limited thereto.

A plurality of first reflective electrodes RE1 and a plurality of second reflective electrodes RE2 which are spaced apart from each other can be disposed on the organic insulating layer 115. The plurality of first reflective electrodes RE1 and the plurality of second reflective electrodes RE2 electrically connect the first light emitting diode 120 and the second light emitting diode 130 to the power line PL, the first driving transistor DT1, and the second driving transistor DT2. Simultaneously, the plurality of first reflective electrodes RE1 and the plurality of second reflective electrodes RE2 serve as reflectors which reflect the light emitted from the first light emitting diode 120 and the second light emitting diode 130 toward the top of the first substrate 110. The plurality of first reflective electrodes RE1 and the plurality of second reflective electrodes RE2 can be formed of a conductive material having excellent reflective property. For example, the plurality of first reflective electrodes RE1 and the plurality of second reflective electrodes RE2 can be formed of a metal material having an excellent reflective property, such as aluminum (Al), silver (Ag), copper (Cu), palladium (Pd), or an alloy thereof, but are not limited thereto.

The plurality of first reflective electrodes RE1 includes a plurality of 1-1-th reflective electrodes RE1a and a plurality of 1-2-th reflective electrodes RE1b. The plurality of 1-1-th reflective electrodes RE1a can be disposed below the first light emitting diode 120 of the plurality of sub pixels SP.

The plurality of 1-1-th reflective electrodes RE1a can electrically connect the first light emitting diode 120 to the first driving transistor DT1. The plurality of 1-1-th reflective electrodes RE1a can be connected to the first source electrode SE1 or the first drain electrode DE1 of the first driving transistor DT1 through a contact hole formed in the organic insulating layer 115. The plurality of 1-1-th reflective electrodes RE1a can be electrically connected to a first p-type electrode 125 of the first light emitting diode 120.

The plurality of 1-2-th reflective electrodes RE1b can electrically connect the second light emitting diode 130 to the second driving transistor DT2. The plurality of 1-2-th reflective electrodes RE1b can be connected to the second source electrode SE2 or the second drain electrode DE2 of the second driving transistor DT2 through a contact hole formed in the organic insulating layer 115. The plurality of 1-2-th reflective electrodes RE1b can be electrically connected to a second p-type electrode 135 of the second light emitting diode 130.

The plurality of second reflective electrodes RE2 can electrically connect the power line PL to the first light emitting diode 120 and the second light emitting diode 130. The plurality of second reflective electrodes RE2 can be electrically connected to the power line PL through a contact hole formed in the organic insulating layer 115. Further, the plurality of second reflective electrodes RE2 can be electrically connected to a common electrode CE through a contact hole of the first planarization layer 116. Accordingly, a first n-type electrode 124 of the first light emitting diode 120 and a second n-type electrode 134 of the second light emitting diode 130 can be electrically connected to the power line PL through the plurality of second reflective electrodes RE2 and the common electrode CE.

In each of the plurality of sub pixels SP, the first light emitting diode 120 is disposed on the 1-1-th reflective electrode RE1a. The first light emitting diode 120 is an element which emits light by a current and can include a light emitting diode which emits red light, green light, and blue light and implement various color light including white by a combination thereof. For example, the first light emitting diode 120 can be a light emitting diode (LED) or a micro LED, but is not limited thereto.

The first light emitting diode 120 is a light emitting diode which displays images to a user who views the display panel PN on the front surface and the side surface of the first substrate 110. For example, when the display device 100 is disposed in the vehicle, the first light emitting diode 120 is a light emitting diode which displays images to the driver and the co-driver in the vehicle. Light emitted from the first light emitting diode 120 can travel toward the front surface and side surface directions of the first substrate 110. At least some of light emitted from the first light emitting diode 120 is reflected by the plurality of first reflective electrodes RE1 and the plurality of second reflective electrodes RE2 to travel toward the front surface and side surface directions of the first substrate 110.

The first light emitting diode 120 can be disposed from a first black bank BB1 and a second black bank BB2 with the same distance. For example, the first light emitting diode 120 can be disposed in a center portion between the first black bank BB1 and the second black bank BB2. Accordingly, an interval of the first light emitting diode 120 and the first black bank BB1 can be the same as a distance between the first light emitting diode 120 and the second black bank BB2.

Each first light emitting diode 120 includes a first n-type semiconductor layer 121, a first emission layer 122, a first p-type semiconductor layer 123, a first n-type electrode 124, a first p-type electrode 125, and a first encapsulation film 126.

The first p-type semiconductor layer 123 is disposed on the 1-1-th reflective electrode RE1a and the first n-type semiconductor layer 121 is disposed on the first p-type semiconductor layer 123. The first p-type semiconductor layer 123 and the first n-type semiconductor layer 121 can be formed by doping p-type and n-type impurities into a specific material. For example, the first p-type semiconductor layer 123 and the first n-type semiconductor layer 121 can be layers doped with p-type and n-type impurities into a material such as gallium nitride (GaN), indium aluminum phosphide (InAlP), or gallium arsenide (GaAs). The n-type impurity can be silicon (Si), germanium (Ge), and tin (Sn), and the p-type impurity can be magnesium (Mg), zinc (Zn), and beryllium (Be), but are not limited thereto.

The first emission layer 122 is disposed between the first p-type semiconductor layer 123 and the first n-type semiconductor layer 121. The first emission layer 122 is supplied with holes and electrons from the first p-type semiconductor layer 123 and the first n-type semiconductor layer 121 to emit light. The first emission layer 122 can be formed with a single layer or a multi-quantum well (MQW) structure, and for example, can be formed of indium gallium nitride (InGaN) or gallium nitride (GaN), but is not limited thereto.

The first p-type electrode 125 is disposed below the first p-type semiconductor layer 123. The first p-type electrode 125 can be disposed on a bottom surface of the first p-type semiconductor layer 123. The first p-type electrode 125 is an electrode for electrically connecting the first light emitting diode 120 and the 1-1-th reflective electrode RE1a and the first driving transistor DT1. The first p-type electrode 125 is in contact with the 1-1-th reflective electrode RE1a to be electrically connected to the 1-1-th reflective electrode RE1a. The first p-type electrode 125 can be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The first n-type electrode 124 is disposed on the first n-type semiconductor layer 121. The first n-type electrode 124 is an electrode which electrically connects the common electrode CE and the first n-type semiconductor layer 121. The first n-type electrode 124 can be formed of the transparent conductive material to allow the light emitted from the first emission layer 122 to be directed to the top of the first substrate 110, for example, the top of the first light emitting diode 120. For example, the first n-type electrode 124 is formed of a transparent conductive material, such as indium tin oxide (ITO) or indium zinc oxide (IZO), but is not limited thereto.

The first encapsulation film 126 is disposed so as to surround at least a part of the first p-type semiconductor layer 123, the first emission layer 122, and the first n-type semiconductor layer 121. The first encapsulation film 126 is formed of an insulating material to protect the first p-type semiconductor layer 123, the first emission layer 122, and the first n-type semiconductor layer 121. The first encapsulation film 126 can cover a side surface of the first p-type semiconductor layer 123, a side surface of the first emission layer 122, and a side surface of the first n-type semiconductor layer 121. Further, the first n-type electrode 124 and the first p-type electrode 125 are exposed from the first encapsulation film 126 to electrically connect the first n-type electrode 124 and the common electrode CE and can electrically connect the first p-type electrode 125 to the 1-1-th reflective electrode RE1a and the first driving transistor DT1. The first encapsulation film 126 is formed of any one of insulating materials, such as silicon oxide (SiOx) or silicon nitride (SiNx), but is not limited thereto.

In each of the plurality of sub pixels SP, the second light emitting diode 130 is disposed on the 1-2-th reflective electrode RE1b. The second light emitting diode 130 is an element which emits light by a current and can include a light emitting diode which emits red light, green light, and blue light and implement various color light including white by a combination thereof. For example, the second light emitting diode 130 can be a light emitting diode (LED) or a micro LED, but is not limited thereto.

The second light emitting diode 130 is a light emitting diode which displays images to a user who views the display panel PN on the front surface and the side surface of the first substrate 110. Light emitted from the second light emitting diode 130 can travel toward the front surface and side surface directions of the first substrate 110. At least some of light emitted from the second light emitting diode 130 is reflected by the plurality of first reflective electrodes RE1 and the plurality of second reflective electrodes RE2 to travel toward the front surface and side surface directions of the first substrate 110.

When the display device 100 is disposed in the vehicle, the second light emitting diode 130 is a light emitting diode which displays images to the co-driver. For example, among light emitted from the second light emitting diode 130, light traveling in a specific direction can be limited. For example, among light emitted from the second light emitting diode 130, traveling of light emitted to a direction in which the driver seat is disposed can be limited. Accordingly, light emitted from the second light emitting diode 130 can be not visible to the driver. In contrast, traveling of light which is emitted to the direction in which the co-driver seat is disposed, among light emitted from the second light emitting diode 130, is not limited and the light can be visible to the co-driver.

The second light emitting diode 130 can be disposed to be adjacent to the first black bank BB1 more than the second black bank BB2. Accordingly, an interval of the second light emitting diode 130 and the first black bank BB1 can be smaller than an interval between the second light emitting diode 130 and the second black bank BB2.

Further, the second light emitting diode 130 can be disposed between the first black bank BB1 and the first light emitting diode 120. The second light emitting diode 130 is disposed to be adjacent to the first black bank BB1 more than the second black bank BB2 so that the second light emitting diode 130 can be disposed between the first black bank BB1 and the first light emitting diode 120.

Each second light emitting diode 130 includes a second n-type semiconductor layer 131, a second emission layer 132, a second p-type semiconductor layer 133, a second n-type electrode 134, a second p-type electrode 135, and a second encapsulation film 136.

The second p-type semiconductor layer 133 is disposed on the 1-2-th reflective electrode RE1b and the second n-type semiconductor layer 131 is disposed on the second p-type semiconductor layer 133. The second p-type semiconductor layer 133 and the second n-type semiconductor layer 131 can be formed by doping p-type and n-type impurities into a specific material. For example, the second n-type semiconductor layer 131 and the second p-type semiconductor layer 133 can be layers doped with p-type and n-type impurities into a material such as gallium nitride (GaN), indium aluminum phosphide (InAlP), or gallium arsenide (GaAs). The n-type impurity can be silicon (Si), germanium (Ge), and tin (Sn), and the p-type impurity can be magnesium (Mg), zinc (Zn), and beryllium (Be), but are not limited thereto.

The second emission layer 132 is disposed between the second n-type semiconductor layer 131 and the second p-type semiconductor layer 133. The second emission layer 132 is supplied with holes and electrons from the second n-type semiconductor layer 131 and the second p-type semiconductor layer 133 to emit light. The second emission layer 132 can be formed by a single layer or a multi-quantum well (MQW) structure, and for example, can be formed of indium gallium nitride (InGaN) or gallium nitride (GaN), but is not limited thereto.

The second p-type electrode 135 is disposed below the second p-type semiconductor layer 133. The second p-type electrode 135 can be disposed on a bottom surface of the second p-type semiconductor layer 133. The second p-type electrode 135 is an electrode for electrically connecting the 1-2-th reflective electrode RE1b and the second driving transistor DT2. The second p-type electrode 135 is in contact with the 1-2-th reflective electrode RE1b to be electrically connected to the 1-2-th reflective electrode RE1b. The second p-type electrode 135 can be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The second n-type electrode 134 is disposed on the second n-type semiconductor layer 131. The second n-type electrode 134 is an electrode for electrically connecting the second light emitting diode 130 to the power line PL together with the second reflective electrode RE2 and the common electrode CE. The second n-type electrode 134 is formed of a transparent conductive material, such as indium tin oxide (ITO) or indium zinc oxide (IZO), but is not limited thereto.

The second encapsulation film 136 is disposed so as to surround at least a part of the second n-type semiconductor layer 131, the second emission layer 132, and the second p-type semiconductor layer 133. The second encapsulation film 136 is formed of an insulating material to protect the second n-type semiconductor layer 131, the second emission layer 132, and the second p-type semiconductor layer 133. The second encapsulation film 136 can cover a side surface of the second n-type semiconductor layer 131, a side surface of the second emission layer 132, and a side surface of the second p-type semiconductor layer 133. Further, the second n-type electrode 134 and the second p-type electrode 135 are exposed from the second encapsulation film 136 to electrically connect the second n-type electrode 134 and the common electrode CE and electrically connect the second p-type electrode 135 to the 1-2-th reflective electrode RE1b and the second driving transistor DT2. The second encapsulation film 136 is formed of any one of insulating materials, such as silicon oxide (SiOx) or silicon nitride (SiNx), but is not limited thereto.

The first planarization layer 116 is disposed on the plurality of first reflective electrodes RE1 and the plurality of second reflective electrodes RE2. The first planarization layer 116 overlaps a part of side portions of the first light emitting diode 120 and the second light emitting diode 130 to fix and protect the first light emitting diode 120 and the second light emitting diode 130. The first planarization layer 116 can be configured by a single layer or a double layer, and for example, can be formed of photoresist or an acrylic-based organic material, but is not limited thereto.

The common electrode CE is disposed on the entire surface of the first substrate 110 on the first planarization layer 116. The common electrodes CE is an electrode which electrically connects the power line PL to the first light emitting diode 120 and the second light emitting diode 130. The common electrodes CE can be electrically connected to the plurality of second reflective electrodes RE2 through a contact hole of the first planarization layer 116. Therefore, the common electrode CE can be electrically connected to the power line PL through the plurality of second reflective electrodes RE2. Further, the common electrode CE can be electrically connected to the first n-type electrode 124 of the first light emitting diodes 120 and the second n-type electrode 315 through a contact hole of the first planarization layer 116.

The common electrode CE is formed of a transparent conductive material to allow light emitted from the first light emitting diode 120 and light emitted from the second light emitting diode 130 to pass through. For example, the common electrode CE is formed of a transparent conductive material, such as indium tin oxide (ITO) or indium zinc oxide (IZO), but is not limited thereto.

The black bank BB which surrounds the plurality of sub pixels SP is disposed on the common electrode CE. The black bank BB can suppress reflection of external light. The black bank BB can be formed of a material which absorbs or blocks light. For example, the black bank BB can be formed of an organic film including a carbon-based black dye.

The black bank BB can block external light which is incident to the display device 100 from being reflected from the metal layer disposed on the first substrate 110 to travel to the outside of the display device 100. For example, the black bank BB can block light which is reflected from the pixel circuit and the reflective electrode RE disposed on the first substrate 110 from traveling to the outside of the display device 100.

Further, the black bank BB can suppress color mixture which can occur between sub pixels SP which emit different color light. For example, the black bank BB is disposed between the adjacent sub pixels SP to absorb or block light which travels to the boundary of the sub pixels SP.

In the meantime, the black bank BB can adjust the viewing angle of the first light emitting diode 120 and the second light emitting diode 130. For example, the black bank BB can block light emitted from the first light emitting diode 120 and the second light emitting diode 130 and limit the viewing angle.

The viewing angles of the black bank BB and the first light emitting diode 120 and the second light emitting diode 130 will be described in detail below with reference to FIGS. 5A and 5B.

The black bank BB can include a first black bank BB1 and a second black bank BB2.

The first black bank BB1 is disposed on one side of each of the plurality of sub pixels SP and the second black bank BB2 can be disposed on the other side of each of the plurality of sub pixels SP. For example, one side is the same direction as the direction in which the driver seat is disposed and the other side can be the same direction as the direction in which the co-driver seat is disposed. For example, with respect to FIGS. 3 and 4, the first black bank BB1 is disposed on a left side of each of the plurality of sub pixels SP and the second black bank BB2 can be disposed on a right side of each of the plurality of sub pixels SP.

A height of the first black bank BB1 and a height of the second black bank BB2 can be equal to each other. For example, both the first black bank BB1 and the second black bank BB2 can be formed by the same process. Accordingly, the first black bank BB1 and the second black bank BB2 can have the same height.

The first black bank BB1 can guide light emitted from the first light emitting diode 120 to be emitted to one side at a wide viewing angle. The first black bank BB1 can guide light emitted from the second light emitting diode 130 to be emitted to one side at a narrow viewing angle.

The second black bank BB2 guides light emitted from the first light emitting diode 120 to be emitted to the other side at a wide viewing angle. The second black bank BB2 can guide light emitted from the second light emitting diode 130 to be emitted to the other side at a wide viewing angle.

The viewing angles of the black bank BB and the first light emitting diode 120 and the second light emitting diode 130 will be described in detail below with reference to FIGS. 5A and 5B.

The second planarization layer 117 is disposed on the common electrode CE and the black bank BB. The second planarization layer 117 can be disposed to fill in a space between the first black bank BB1 and the second black bank BB2. For example, a top surface of the second planarization layer 117 can be disposed on the same plane as top surfaces of the first black bank BB1 and the second black bank BB2. The second planarization layer 117 can be configured by a single layer or a double layer, and for example, can be formed of photoresist or an acrylic-based organic material, but is not limited thereto.

The protection layer 118 is disposed on the second planarization layer 117 and the black bank BB. The protection layer 118 is a layer for protecting components below the protection layer 118, and can be configured by a single layer or a double layer of translucent epoxy, silicon oxide (SiOx) or silicon nitride (SiNx), but is not limited thereto.

The protection layer 118 can have a flat bottom surface and a flat top surface. For example, the bottom surface of the protection layer 118 can be in contact with a top surface of the second planarization layer 117, a top surface of the first black bank BB1, and a top surface of the second black bank BB2 which are disposed on the same plane. The top surface of the protection layer 118 can be in contact with a bottom surface of the second substrate 119.

The second substrate 119 is disposed on the protective layer 118. The second substrate 119 is a configuration for protecting the display device 100 and can be formed of an insulating material. For example, the second substrate 119 can be formed of glass or resin.

In the meantime, an optical film, such as an anti-scattering film, an anti-glare film, an anti-reflecting film, a low-reflecting film, an Oled transmittance controllable film, or a polarizer, can be further disposed above or below the second substrate 119, but is not limited thereto.

Hereinafter, the viewing angles of the black bank BB, the first light emitting diode 120, and the second light emitting diode 130 will be described with reference to FIGS. 5A and 5B.

FIG. 5A is a schematic view illustrating a viewing angle of a first light emitting diode of a display device according to an example embodiment of the present disclosure. FIG. 5B is a schematic view illustrating a viewing angle of a second light emitting diode of a display device according to an example embodiment of the present disclosure. The viewing angles of the first light emitting diode 120 and the second light emitting diode 130 refer to a maximum angle between light emitted from the first light emitting diode 120 and the second light emitting diode 130 and a normal line of the display device 100. In FIGS. 5A and 5B, for the convenience of description, the first light emitting diode 120, the second light emitting diode 130, the first black bank BB1, and the second black bank BB2 are illustrated.

The viewing angles of the first light emitting diode 120 and the second light emitting diode 130 can be determined by an interval between the first light emitting diode 120 and the second light emitting diode 130 and the black bank BB and the height of the black bank BB. For example, when a viewing angle of the first light emitting diode 120 for one side is θ2, a height of the first black bank BB1 is H, and an interval between the first light emitting diode 120 and the first black bank BB1 is A, tan(θ2)=A/H. Further, when a viewing angle of the second light emitting diode 130 for one side is θ3, a height of the first black bank BB1 is H, and an interval between the second light emitting diode 130 and the first black bank BB1 is B, tan(θ3)=B/H. Accordingly, the smaller the interval between the first light emitting diode 120 and the second light emitting diode 130 and the black bank BB, the smaller the viewing angle of the first light emitting diode 120 and the second light emitting diode 130. Further, the second light emitting diode 130 is disposed to be adjacent to the first black bank BB1, more than the first light emitting diode 120 so that the viewing angle of the second light emitting diode 130 for a direction in which the first black bank BB is disposed is smaller than the viewing angle of the first light emitting diode 120. Further, the larger the height of the black bank BB, the smaller the viewing angle of the first light emitting diode 120 and the second light emitting diode 130.

Referring to FIG. 5A, the first light emitting diode 120 is spaced apart from the first black bank BB1 and the second black bank BB2 with the same interval and the first black bank BB1 and the second black bank BB2 have the same height. Accordingly, the viewing angle of the first light emitting diode 120 for the other side can be equal to the viewing angle of the first light emitting diode 120 for one side.

For example, a width of one sub pixel SP is assumed as approximately 42.6 μm. At this time, when the first light emitting diode 120 is disposed in the center portion of each sub pixel SP, the center of the first light emitting diode 120 can be spaced apart from an end of the first black bank BB1 by approximately 21.3 μm and can be spaced apart from an end of the second black bank BB2 by approximately 21.3 μm.

At this time, when the height of the first black bank BB1 and the second black bank BB2 is approximately 12.3 μm or smaller, the viewing angle of the first light emitting diode 120 toward the direction in which the first black bank BB1 is disposed and the direction in which the second black bank BB2 is disposed can be 60 degrees or larger.

Referring to FIG. 5B, the second light emitting diode 130 is spaced apart from the first black bank BB1 and the second black bank BB2 with different intervals, respectively. Accordingly, the viewing angle of the second light emitting diode 130 for the other side can be different from the viewing angle of the second light emitting diode 130 for one side.

Specifically, when a direction in which the first black bank BB1 is disposed with respect to the center of the second light emitting diode 130 is one side and a direction in which the second black bank BB2 is disposed is the other side, a viewing angle of the second light emitting diode 130 for one side can be smaller than a viewing angle of the second light emitting diode 130 for the other side.

In the meantime, the second light emitting diode 130 is disposed to be adjacent to the first black bank BB1, more than the first light emitting diode 120. Accordingly, the viewing angle of the second light emitting diode 130 for one side can be smaller than the viewing angle of the first light emitting diode 120 for one side.

For example, it is assumed that a minimum interval between a center of the second light emitting diode 130 in consideration of a process deviation and an end of the first black bank BB1 is 8 μm. Further, the center of the first light emitting diode 120 is spaced apart from one end of the first black bank BB1 and an end of the second black bank BB2 by approximately 21.3 μm. It is assumed that a minimum interval between a center of the first light emitting diode 120 in consideration of a process deviation and a center of the second light emitting diode 130 is approximately 8 μm. In this case, the interval between the end of the first black bank BB1 and the center of the second light emitting diode 130 can be approximately 13 μm. Further, accordingly, the second light emitting diode 130 can be disposed to be spaced apart from the end of the first black bank BB1 by approximately 8 μm to 13 μm.

At this time, when the height of the first black bank BB1 is approximately 10 μm, the viewing angle of the second light emitting diode 130 toward a direction in which the first black bank BB1 is disposed can be 50 degrees or smaller. Further, when the height of the first black bank BB1 is approximately 7.5 μm, the viewing angle of the second light emitting diode 130 toward a direction in which the first black bank BB1 is disposed can be 50 degrees or smaller. However, when the height of the first black bank BB1 is approximately 5 μm, the viewing angle of the second light emitting diode 130 toward a direction in which the first black bank BB1 is disposed can exceed 55 degrees.

A co-driver display can be disposed on the vehicle dash board in the front surface direction of the co-driver seat to provide convenience for a co-driver in the co-driver seat. For example, the co-driver display can provide information, which is irrelevant to the vehicle operation, for example, information about entertainment, such as dramas, movies, or music. However, in order to ensure the safety of the vehicle operation, the co-driver display needs to selectively provide images to a direction in which the driver seat is disposed. For example, the co-driver display controls the viewing angle to allow the driver and the co-driver to watch the images in a vehicle stop state together and controls the viewing angle to allow only the co-driver to watch the images in a vehicle driving state. For example, the co-driver display needs to control the viewing angle to have various viewing angles in the vehicle stop state and the vehicle driving state.

In the display device 100 according to the example embodiment of the present disclosure, in one sub pixel SP, the position of the first light emitting diode 120 and the second light emitting diode 130 and the black bank BB is adjusted to control the viewing angles of the first light emitting diode 120 and the second light emitting diode 130. For example, as the interval between the black bank BB and the first light emitting diode 120 and the second light emitting diode 130 is reduced and the height of the black bank BB is increased, the viewing angle of the first light emitting diode 120 and the second light emitting diode 130 can be limited. At this time, when the first light emitting diode 120 is disposed in the center portion of the sub pixel SP, the first light emitting diode 120 can have a wide viewing angle in all directions. Accordingly, light emitted from the first light emitting diode 120 can be visible in all side directions. In contrast, when the second light emitting diode 130 is disposed in the side portion of the sub pixel SP, the second light emitting diode 130 can have different viewing angles according to the direction. Accordingly, light emitted from the second light emitting diode 130 can be not visible in one direction, but be visible in the other direction. Accordingly, in the display device 100 according to the example embodiment of the present disclosure, the interval of the second light emitting diode 130 and the black bank BB is adjusted to selectively have a narrow viewing angle in a specific area.

Further, in the display device 100 according to the example embodiment of the present disclosure, the viewing angles of the first light emitting diode 120 and the second light emitting diode 130 can be controlled using only the black bank BB. Accordingly, in the display device 100 according to the example embodiment of the present disclosure, a separate component for controlling a viewing angle is not required to reduce a manufacturing process of the display device 100 to reduce a manufacturing cost and a product cost.

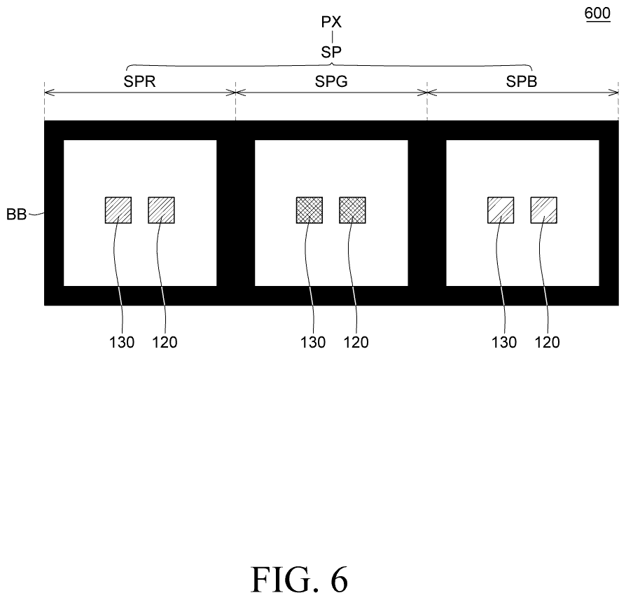

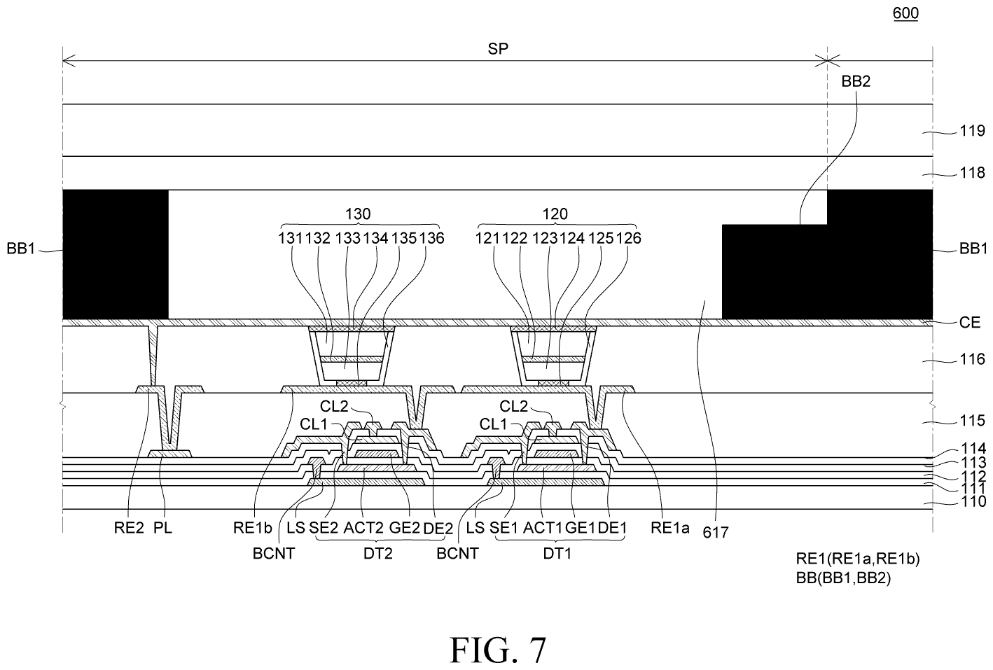

FIG. 6 is an enlarged plan view of a display area of a display device according to another example embodiment of the present disclosure. FIG. 7 is a cross-sectional view of a sub pixel of a display device according to another example embodiment of the present disclosure. A display device 600 of FIGS. 6 and 7 is substantially the same as the display device 100 of FIGS. 1 to 4 except for a black bank BB, a second planarization layer 617, and a position of the first light emitting diode 120 and the second light emitting diode 130, so that a redundant description is omitted or may be briefly provided.

Referring to FIG. 6, the first light emitting diode 120 and the second light emitting diode 130 are disposed in the plurality of sub pixels SP. In each of the plurality of sub pixels SP, the first light emitting diode 120 and the second light emitting diode 130 can be disposed in the same rows and different columns.

The configuration of the first light emitting diode 120 and the second light emitting diode 130 of FIGS. 6 and 7 is substantially the same as the configuration of the first light emitting diode 120 and the second light emitting diode 130 of FIGS. 1 to 5B except for the position disposed in the sub pixel SP, so that a redundant description will be omitted.

Referring to FIG. 7 together, the first light emitting diode 120 and the second light emitting diode 130 can be disposed on both sides of each sub pixel SP. For example, the first light emitting diode 120 is disposed on the right side from the center portion of the sub pixel SP and the second light emitting diode 130 can be disposed on the left side from the center portion of the sub pixel SP. For example, in the row direction, the shortest distance between the first light emitting diode 120 and the black bank BB can be the same as the shortest distance between the second light emitting diode 130 and the black bank BB, but is not limited thereto.

In one sub pixel SP, only one of the first light emitting diode 120 and the second light emitting diode 130 can be selectively driven. For example, the first light emitting diode 120 can be driven in the vehicle stop state and the second light emitting diode 130 can be driven in the vehicle driving state.

Light emitted from the first light emitting diode 120 can be configured to have a wide viewing angle toward the driver seat and the co-driver seat. Accordingly, light emitted from the first light emitting diode 120 can be visible to both the driver and the co-driver. In contrast, light emitted from the second light emitting diode 130 can be configured to have a narrow viewing angle in a drive seat direction and a wide viewing angle in a co-driver seat direction. Accordingly, light emitted from the second light emitting diode 130 can be not visible to the driver, but be visible to the co-driver.

The black bank BB is disposed between the plurality of sub pixels SP. The black bank BB can include a first black bank BB1 and a second black bank BB2.

The first black bank BB1 is disposed on one side and the other side of each of the plurality of sub pixels SP and the second black bank BB2 can be disposed on the other side of each of the plurality of sub pixels SP. For example, one side is the same direction as the direction in which the driver seat is disposed and the other side can be the same direction as the direction in which the co-driver seat is disposed. For example, with respect to FIGS. 6 and 7, the first black bank BB1 is disposed on a left side of each of the plurality of sub pixels SP and the second black bank BB2 can be disposed on a right side of each of the plurality of sub pixels SP.

A height of the first black bank BB1 and a height of the second black bank BB2 can be different from each other. For example, the second black bank BB2 has a height smaller than that of the first black bank BB1.

Both the first black bank BB1 and the second black bank BB2 can be formed by the same process. For example, the second black bank BB2 is formed using a halftone mask to have a height different from that of the first black bank BB1 to have a step. Alternatively, the first black bank BB1 and the second black bank BB2 can be separately formed by different processes.

The first black bank BB1 can guide light emitted from the first light emitting diode 120 to be emitted to one side at a wide viewing angle. The first black bank BB1 can guide light emitted from the second light emitting diode 130 to be emitted to one side at a narrow viewing angle.

The second black bank BB2 has a height lower than that of the first black bank BB1 to guide light emitted from the first light emitting diode 120 and light emitted from the second light emitting diode 130 to be emitted to the other side with a wide viewing angle.

In the meantime, the light traveling to the other side from the first light emitting diode 120 can also be guided by the first black bank BB1 of the adjacent sub pixel SP. For example, among light emitted from the first light emitting diode 120, light traveling to the right side with respect to FIG. 7 can be guided by the second black bank BB2 and/or the first black bank BB1 adjacent to the second black bank BB2.

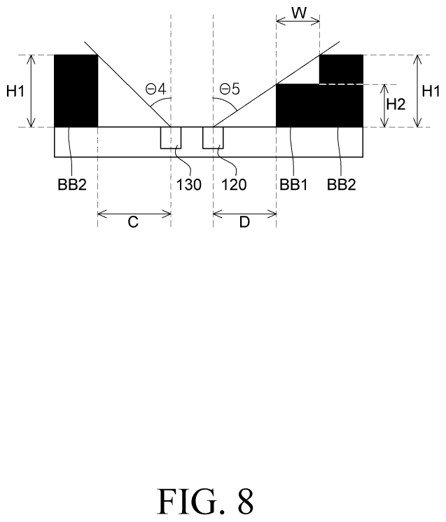

The viewing angles of the black bank BB and the first light emitting diode 120 and the second light emitting diode 130 will be described in detail below with reference to FIG. 8.

The second planarization layer 617 is disposed on the black bank BB. The second planarization layer 617 can be disposed to fill in a space between the first black bank BB1 and the second black bank BB2. Further, the second planarization layer 617 can fill in a step between a top surface of the first black bank BB1 and a top surface of the second black bank BB2. For example, the top surface of the second planarization layer 617 can be disposed on the same plane as the top surface of the second black bank BB2. At this time, the second planarization layer 617 can cover the top surface of the second black bank BB2 and a side surface of the first black bank BB1 exposed by the second black bank BB2.

Hereinafter, the viewing angles of the black bank BB and the first light emitting diode 120 and the second light emitting diode 130 will be described with reference to FIG. 8.

FIG. 8 is a schematic view of a viewing angle of a sub pixel of a display device according to another example embodiment of the present disclosure. The viewing angles of the first light emitting diode 120 and the second light emitting diode 130 refer to a maximum angle between light emitted from the first light emitting diode 120 and the second light emitting diode 130 and a normal line of the display device 100. In FIG. 8, for the convenience of description, only the first light emitting diode 120, the second light emitting diode 130, the first black bank BB1, and the second black bank BB2 are illustrated.

The viewing angles of the first light emitting diode 120 and the second light emitting diode 130 can be determined by an interval between the first light emitting diode 120 and the second light emitting diode 130 and the black bank BB and the height of the black bank BB. For example, the smaller the interval between the first light emitting diode 120 and the second light emitting diode 130 and the black bank BB, the smaller the viewing angle of the first light emitting diode 120 and the second light emitting diode 130. Further, the larger the height of the black bank BB, the smaller the viewing angle of the first light emitting diode 120 and the second light emitting diode 130.

Hereinafter, for the convenience of description, it is assumed that with respect to the center of the first light emitting diode 120, a direction in which the first black bank BB1 is disposed is one side and a direction in which the second black bank BB2 is disposed is the other side.

Referring to FIG. 8, the first light emitting diode 120 is spaced apart from the first black bank BB1 and the second black bank BB2 with different intervals, respectively. Accordingly, the viewing angle of the first light emitting diode 120 for the other side can be different from the viewing angle of the first light emitting diode 120 for one side. Further, the second light emitting diode 130 is spaced apart from the first black bank BB1 and the second black bank BB2 with different intervals, respectively. Accordingly, the viewing angle of the second light emitting diode 130 for the other side can be different from the viewing angle of the second light emitting diode 130 for one side.

The second light emitting diode 130 is disposed to be adjacent to the first bank BB1, more than the first light emitting diode 120. Accordingly, the viewing angle of the second light emitting diode 130 for one side is smaller than the viewing angle of the first light emitting diode 120 for one side. Further, the first light emitting diode 120 is disposed to be adjacent to the second black bank BB2, more than the second light emitting diode 130. Accordingly, the viewing angle of the first light emitting diode 120 for the other side can be smaller than the viewing angle of the second light emitting diode 130 for the other side.

In the meantime, the second black bank BB2 has a height smaller than that of the first black bank BB1. Accordingly, the viewing angle of the second light emitting diode 130 for one side is different from the viewing angle of the first light emitting diode 120 for the other side. For example, when a viewing angle of the second light emitting diode 130 for one side is θ4, a height of the first black bank BB1 is H1, and an interval between the second light emitting diode 130 and the first black bank BB1 is C, tan(θ4)=C/H1. When a viewing angle of the first light emitting diode 120 for the other side is θ5, a height of the second black bank BB2 is H2, and an interval between the first light emitting diode 120 and the second black bank BB2 is D, tan(θ5)=D/H2. Therefore, even though H1 is equal to H2, if C is different from D, 04 and 05 can be different.

Hereinafter, in Table 1, a position of the second light emitting diode 130 and the height of the first black bank BB1 to form a viewing angle of the second light emitting diode 130 for one side to be 50 degrees or smaller are summarized.

TABLE 1

| Distance between center of second light emitting | Height of first |
|---|---|
| diode and end of first black bank (μm) | black bank (μm) |
| 8 | ≥6.7 |
| 9 | ≥7.5 |
| 10 | ≥8.4 |
| 11 | ≥9.2 |
| 12 | ≥10.0 |
| 13 | ≥10.9 |
| 14 | ≥11.7 |
| 15 | ≥12.6 |

Referring to Table 1, it is confirmed that the larger the distance between the center of the second light emitting diode 130 and the end of the first black bank BB1, the larger the minimum height of the second black bank BB2 to form the viewing angle of the second light emitting diode 130 for one side to be 50 degrees or smaller.

Hereinafter, in Table 2, a position of the first light emitting diode 120 and the height of the second black bank BB2 to form a viewing angle of the first light emitting diode 120 for the other side to be 60 degrees or larger are summarized.

TABLE 2

| Distance between center of first light emitting | Height of second |
|---|---|
| diode and end of second black bank (μm) | black bank (μm) |
| 8 | ≤4.6 |
| 9 | ≤5.2 |
| 10 | ≤5.8 |
| 11 | ≤6.4 |
| 12 | ≤6.9 |

Referring to Table 2, it is confirmed that the larger the distance between the center of the first light emitting diode 120 and the end of the second black bank BB2, the larger the minimum height of the second black bank BB2 to form the viewing angle of the first light emitting diode 120 for the other side to be 50 degrees or smaller.

Referring to Tables 1 and 2 together, even though the distance between the center of the first light emitting diode 120 and the end of the second black bank BB2 and the distance between the center of the second light emitting diode 130 and the end of the first black bank BB1 are equal, if the height of the first black bank BB1 and the height of the second black bank BB2 are different, it can be confirmed that the viewing angle of the second light emitting diode 130 for one side and the viewing angle of the first light emitting diode 120 for the other side are different. For example, when the distance between the center of the first light emitting diode 120 and the end of the second black bank BB2 and the distance between the center of the second light emitting diode 130 and the end of the first black bank BB1 are approximately 8 μm, if the height of the first black bank BB1 is approximately 6.7 μm, it is confirmed that the viewing angle of the second light emitting diode 130 for one side is 50 degrees or smaller. Further, it is further confirmed that if the height of the second black bank BB2 is approximately 4.6 μm, the viewing angle of the first light emitting diode 120 for the other side is 60 degrees or larger. Accordingly, even though the shortest distance between the first light emitting diode 120 and the black bank BB and the shortest distance between the second light emitting diode 130 and the black bank BB are equal to each other, the viewing angle of the first light emitting diode 120 for one side and the viewing angle of the second light emitting diode 130 for the other side can be different from each other depending on the height of the first black bank BB1 and the height of the second black bank BB2.

In the meantime, a viewing angle of light of the first light emitting diode 120 directed to the direction in which the second black bank BB2 is disposed is also guided by the first black bank BB1 disposed in the other adjacent sub pixel SP. For example, as the height difference of the second black bank BB2 and the first black bank BB1 is large or the width of the first black bank BB1 is smaller, the viewing angle of light of the first light emitting diode 120 traveling to the direction in which the second black bank BB2 is disposed is reduced by the first black bank BB1 disposed in the other adjacent sub pixel SP.

For example, referring to FIG. 8, when the width of the second black bank BB2 is W, a height difference H1−H2 of the first black bank BB1 and the second black bank BB2, and the viewing angle of the first light emitting diode 120 which travels toward the direction in which the second black bank BB2 is disposed is θ5, tan(θ5)=W/(H1−H2). However, when the height difference of the second black bank BB2 and the first black bank BB1 is small or the width of the first black bank BB1 and the second black bank BB2 is larger, the light of the first light emitting diode 120 in which the viewing angle is limited by the second black bank BB2 can be visible to the driver and the co-driver without being limited by the first black bank BB1 disposed in another adjacent sub pixel SP.

For example, it is assumed that a minimum interval between the center of the second light emitting diode 130 in consideration of the process deviation and the end of the first black bank BB1 is approximately 9 μm and a minimum interval between the center of the first light emitting diode 120 and the end of the second black bank BB2 is approximately 9.5 μm. Further, it is assumed that the minimum interval between the center of the first light emitting diode 120 and the center of the second light emitting diode 130 is approximately 8 μm.

At this time, when the height of the first black bank BB1 is approximately 7.5 μm, the viewing angle of the second light emitting diode 130 toward a direction in which the first black bank BB1 is disposed can be 50 degrees or smaller. Further, when the height of the second black bank BB2 is approximately 5.6 μm, the viewing angle of the first light emitting diode 120 toward a direction in which the second black bank BB2 is disposed can be 60 degrees or larger. At this time, when the width of each of the first black bank BB1 and the second black bank BB2 is approximately 5 μm, the height difference of the second black bank BB2 and the first black bank BB1 is approximately 1.9 μm. Accordingly, light whose viewing angle is limited to approximately 60 degrees by the second black bank BB2 is visible to the driver and the co-driver without being limited by the first black bank BB1 disposed in the other adjacent sub pixel SP.

In the display device 600 according to another example embodiment of the present disclosure, in one sub pixel SP, the position of the first light emitting diode 120 and the second light emitting diode 130 and the black bank BB is adjusted to control the viewing angles of the first light emitting diode 120 and the second light emitting diode 130. For example, as the interval between the black bank BB and the first light emitting diode 120 and the second light emitting diode 130 is reduced and the height of the black bank BB is increased, the viewing angle of the first light emitting diode 120 and the second light emitting diode 130 can be limited. Accordingly, when the first black bank BB1 is disposed in one side of each of the plurality of sub pixels SP and the second black bank BB2 is disposed in the other side, the second light emitting diode 130 which is disposed to be adjacent to the first black bank BB1 can have a narrow viewing angle for one side more than the first light emitting diode 120 which is spaced apart from the first black bank BB1. Accordingly, in the display device 600 according to another example embodiment of the present disclosure, the interval of the first light emitting diode 120 and the second light emitting diode 130 and the black bank BB is adjusted to selectively have a narrow viewing angle in a specific area.

Further, in the display device 600 according to another example embodiment of the present disclosure, the viewing angles of the first light emitting diode 120 and the second light emitting diode 130 can be controlled using only the black bank BB. Therefore, the manufacturing process of the display device 600 is reduced to reduce the manufacturing cost and the product cost.

Further, in the display device 600 according to another example embodiment of the present disclosure, in one sub pixel SP, heights of the second black bank BB2 disposed on the other side of each of the plurality of sub pixels SP are different. Accordingly, the first light emitting diode 120 disposed to be adjacent to the second black bank BB2 has wide viewing angles in both one side and the other side. Therefore, the first light emitting diode 120 can have a wide viewing angle in a direction in which the second black bank BB2 is disposed without increasing the interval of the first light emitting diode 120 and the second black bank BB2 so that a size of each of the plurality of sub pixels SP is reduced to implement a display device 600 with a high resolution.

The example embodiments of the present disclosure can also be described as follows:

According to an aspect of the present disclosure, a display device includes a substrate including a plurality of sub pixels, a black bank surrounding each of the plurality of sub pixels, and a plurality of light emitting diodes in the plurality of sub pixels. The plurality of light emitting diodes includes a first light emitting diode and a second light emitting diode disposed in each of the plurality of sub pixels and emitting the same color light. A shortest distance between the first light emitting diode and the black bank is longer than a shortest distance between the second light emitting diode and the black bank.

The first light emitting diode and the second light emitting diode can be disposed in the same row and different columns and a shortest distance between the first light emitting diode and the black bank in a row direction can be longer than a shortest distance between the second light emitting diode and the black bank in the row direction.

In each of the plurality of sub pixels, only any one of the first light emitting diode and the second light emitting diode can be selectively driven.

The black bank can include a first black bank disposed in one side of each of the plurality of sub pixels; and a second black bank disposed in the other side of each of the plurality of sub pixels. The first light emitting diode can be disposed to be spaced apart from the first black bank with the same distance from the second black bank and the second light emitting diode can be disposed to more adjacent to the first black bank than the second black bank.

A viewing angle of the second light emitting diode for one side can be smaller than a viewing angle of the second light emitting diode for the other side.

The second light emitting diode can be disposed between the first black bank and the first light emitting diode.

A viewing angle of the second light emitting diode for one side can be smaller than a viewing angle of the first light emitting diode for one side.

The viewing angle of the second light emitting diode for one side can be 50 degrees or smaller and the viewing angle of the first light emitting diode for one side can be 60 degrees or larger.

The viewing angle of the first light emitting diode for the other side can be equal to the viewing angle of the first light emitting diode for one side.

The display device can be a display device for a vehicle and the one side can be the same direction as a direction in which a driver seat is disposed and the other side can be the same direction as a direction in which a co-driver seat is disposed.

The first light emitting diode can be driven in a vehicle stop state and the second light emitting diode can be driven in a vehicle operation state.

A height of the first black bank can be equal to a height of the second black bank.

According to another aspect of the present disclosure, a display device includes a substrate including a plurality of sub pixels, a plurality of light emitting diodes in the plurality of sub pixels, and a black bank surrounding each of the plurality of sub pixels. The plurality of light emitting diodes includes a first light emitting diode in each of the plurality of sub pixels and a second light emitting diode emitting the same color light as the first light emitting diode. The black bank has different heights in one side and the other side of the plurality of sub pixels.

The black bank can include a first black bank spaced apart from the first light emitting diode and the second light emitting diode to one side in each of the plurality of sub pixels; and a second black bank spaced apart from the first light emitting diode and the second light emitting diode to the other side in each of the plurality of sub pixels. The second black bank can have a height lower than that of the first black bank.

A viewing angle of the first light emitting diode for one side can be different from a viewing angle of the first light emitting diode for the other side and a viewing angle of the second light emitting diode for one side can be different from a viewing angle of the second light emitting diode for the other side.

A viewing angle of the second light emitting diode for one side can be smaller than a viewing angle of the first light emitting diode for one side.

The viewing angle of the second light emitting diode for one side can be 50 degrees or smaller and the viewing angle of the first light emitting diode for one side can be 60 degrees or larger.

A shortest distance between the first light emitting diode and the black bank can be equal to a shortest distance between the second light emitting diode and the black bank.

In each of the plurality of sub pixels, only any one of the first light emitting diode and the second light emitting diode can be selectively driven.

The display device can be a display device for a vehicle and the first light emitting diode can be driven in a stop state and the second light emitting diode can be driven in an operating state.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a plurality of sub pixels;
a black bank disposed adjacent to each of the plurality of sub pixels; and
a plurality of light emitting diodes in the plurality of sub pixels,
wherein the plurality of light emitting diodes includes a first light emitting diode and a second light emitting diode disposed in each of the plurality of sub pixels and configured to emit a same color light, and
wherein a shortest distance between the first light emitting diode and the black bank is longer than a shortest distance between the second light emitting diode and the black bank.

2. The display device according to claim 1, wherein the first light emitting diode and the second light emitting diode are disposed in a same row and in different columns, and
wherein a shortest distance between the first light emitting diode and the black bank in a row direction is longer than a shortest distance between the second light emitting diode and the black bank in the row direction.

3. The display device according to claim 1, wherein in each of the plurality of sub pixels, only one of the first light emitting diode and the second light emitting diode is selectively driven.

4. The display device according to claim 1, wherein the black bank includes:
a first black bank disposed in one side of each of the plurality of sub pixels; and
a second black bank disposed in another side of each of the plurality of sub pixels,
wherein the first light emitting diode is disposed to be spaced apart from the first black bank with a same distance from the second black bank, and
wherein the second light emitting diode is disposed to be more adjacent to the first black bank than the second black bank.

5. The display device according to claim 4, wherein a viewing angle of the second light emitting diode for the one side of each of the plurality of sub pixels is smaller than a viewing angle of the second light emitting diode for the another side of each of the plurality of sub pixels.

6. The display device according to claim 4, wherein the second light emitting diode is disposed between the first black bank and the first light emitting diode.

7. The display device according to claim 4, wherein a viewing angle of the second light emitting diode for the one side of each of the plurality of sub pixels is smaller than a viewing angle of the first light emitting diode for the one side of each of the plurality of sub pixels.

8. The display device according to claim 4, wherein a viewing angle of the second light emitting diode for the one side of each of the plurality of sub pixels is 50 degrees or smaller and a viewing angle of the first light emitting diode for the one side of each of the plurality of sub pixels is 60 degrees or larger.

9. The display device according to claim 4, wherein a viewing angle of the first light emitting diode for the another side of each of the plurality of sub pixels is equal to a viewing angle of the first light emitting diode for the one side of each of the plurality of sub pixels.

10. The display device according to claim 4, wherein the display device is a display device for a vehicle, and
wherein the one side of each of the plurality of sub pixels is s same direction as a direction in which a driver seat is disposed and the another side of each of the plurality of sub pixels is a same direction as a direction in which a co-driver seat is disposed.

11. The display device according to claim 10, wherein the first light emitting diode is driven in a vehicle stop state and the second light emitting diode is driven in a vehicle operation state.

12. The display device according to claim 4, wherein a height of the first black bank is equal to a height of the second black bank.

13. A display device comprising:
a substrate including a plurality of sub pixels;
a plurality of light emitting diodes in the plurality of sub pixels; and
a black bank disposed adjacent to each of the plurality of sub pixels,
wherein the plurality of light emitting diodes includes:
a first light emitting diode in each of the plurality of sub pixels; and
a second light emitting diode configured to emit a same color light as the first light emitting diode, and
wherein the black bank has different heights in one side and another side of the plurality of sub pixels.

14. The display device according to claim 13, wherein the black bank includes:
a first black bank spaced apart from the first light emitting diode and the second light emitting diode, and disposed in the one side of the plurality of sub pixels, in each of the plurality of sub pixels; and
a second black bank spaced apart from the first light emitting diode and the second light emitting diode, and disposed in the another side of the plurality of sub pixels in each of the plurality of sub pixels, and
wherein the second black bank has a height lower than a height of the first black bank.

15. The display device according to claim 14, wherein a viewing angle of the first light emitting diode for the one side of the plurality of sub pixels is different from a viewing angle of the first light emitting diode for the another side of the plurality of sub pixels, and
wherein a viewing angle of the second light emitting diode for the one side of the plurality of sub pixels is different from a viewing angle of the second light emitting diode for the another side of the plurality of sub pixels.

16. The display device according to claim 14, wherein a viewing angle of the second light emitting diode for the one side of the plurality of sub pixels is smaller than a viewing angle of the first light emitting diode for the one side of the plurality of sub pixels.

17. The display device according to claim 14, wherein a viewing angle of the second light emitting diode for the one side of the plurality of sub pixels is 50 degrees or smaller, and a viewing angle of the first light emitting diode for the one side of the plurality of sub pixels is 60 degrees or larger.

18. The display device according to claim 13, wherein a shortest distance between the first light emitting diode and the black bank is equal to a shortest distance between the second light emitting diode and the black bank.

19. The display device according to claim 13, wherein in each of the plurality of sub pixels, only one of the first light emitting diode and the second light emitting diode is selectively driven.

20. The display device according to claim 19, wherein the display device is a display device for a vehicle, and
wherein the first light emitting diode is driven in a stop state and the second light emitting diode is driven in an operating state.
